(19) United States
(12) Patent Application Publication
(10) Pub. No.: US 2025/0378991 A1
(43) Pub. Date: Dec. 11, 2025

(54) CONFIGURABLE TRANSFORMER-BASED VOLTAGE MATCHING METHOD FOR AUDIO NOTIFICATION APPLIANCE CIRCUITS

(71) Applicant: Tyco Fire & Security GmbH, Neuhausen am Rheinfall (CH)

(72) Inventor: Sai Chun TANG, Westford, MA (US)

(21) Appl. No.: 18/738,799

(22) Filed: Jun. 10, 2024

(51) Int. Cl. H01F 38/14; G08B 3/00; H03F 3/183

(52) U.S. Cl. CPC H01F 38/14; H03F 3/183; G08B 3/00; H01F 2038/143

(57) ABSTRACT

Some non-limiting aspects of the present disclosure allows an audio notification appliance circuit (NAC) to manage an output voltage for an alarm system by providing a low-cost and energy-efficient method to step up an amplifier output voltage to a required level using configurable transformer winding connections. With this method, only one product is needed to provide a first output voltage or a second output voltage and the amplifier power stage may operate at low voltage levels.

### FIELD

The present disclosure relates generally to premises safety/automation systems, and more specifically, to voltage matching audio notification appliance circuits.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

An example aspect includes an audio notification appliance circuit (NAC) configured to manage an output voltage for an alarm system. The alarm system comprises at least one configurable transformer having at least one secondary winding and at least one primary winding. The at least one configurable transformer is configured to set an output NAC voltage level to a first voltage or a second voltage based on connecting the at least one secondary winding, the at least one primary winding, or the at least one configurable transformer in parallel connection or series connection, and a number of the at least one configurable transformer, a number of the at least one secondary winding, or a number of the at least one primary winding. The alarm system also comprises at least one toggle is configured to, in response to receiving a command, switch a connection of the at least one secondary winding in parallel connection or series connection, a connection of the at least one primary winding in parallel connection or series connection, or a connection of the at least one configurable transformer in parallel connection or series connection. The alarm system further comprises an amplifier configured to adjust the output NAC voltage level to either the first voltage or the second voltage.

Another example aspect includes a method of controlling an alarm system. The method includes providing an audio notification appliance circuit (NAC) for managing an output voltage of the alarm system. The NAC comprising at least one configurable transformer having at least one secondary winding and at least one primary winding. The at least one configurable transformer is configured to set an output NAC voltage level to a first voltage or a second voltage based on a combination of connecting the at least one secondary winding, the at least one primary winding, or the at least one configurable transformer in parallel connection or series connection, and a number of the at least one configurable transformer, a number of the at least one secondary winding, or a number of the at least one primary winding. The NAC also comprises at least one toggle configured to, in response to receiving a command, switch a connection of the at least one secondary winding in parallel connection or series connection, a connection of the at least one primary winding in parallel connection or series connection, or a connection of the at least one configurable transformer in parallel connection or series connection. The NAC further comprises an amplifier configured to adjust the output NAC voltage level. The method also includes outputting the first voltage or the second voltage in response the combination of connecting the at least one secondary winding, the at least one primary winding, or the at least one configurable transformer in parallel connection or series connection and the number of the at least one configurable transformer, a number of the at least one secondary winding, or a number of the at least one primary winding and a selection of the at least one toggle.

A further example aspect includes an alarm system comprising at least one audible alarm to generate an audible signal. The alarm system also comprises an audio notification appliance circuit (NAC) for managing an output voltage of the at least one audible alarm. The NAC comprises at least one configurable transformer having at least one secondary winding and at least one primary winding. The at least one configurable transformer is configured to set an output NAC voltage level to a first voltage or a second voltage based on connecting the at least one secondary winding, the at least one primary winding, or the at least one configurable transformer in parallel connection or series connection, and a number of the at least one configurable transformer, a number of the at least one secondary winding, or a number of the at least one primary winding. The NAC also comprises at least one toggle configured to, in response to receiving a command, switch a connection of the at least one secondary winding in parallel connection or series connection, a connection of the at least one primary winding in parallel connection or series connection, or a connection of the at least one configurable transformer in parallel connection or series connection. The NAC further comprises an amplifier configured to adjust the output NAC voltage level to either the first voltage or the second voltage.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a schematic diagram of a transformer for boosting an output voltage of an amplifier to a required audio notification appliance circuit (NAC) voltage, according to some aspects of the present disclosure;

FIG. 2A is a schematic diagram of an implementation of a transformer with at least two secondary windings that can be connected in parallel connection, according to some aspects of the present disclosure;

FIG. 2B is a schematic diagram of an implementation of a transformer with at least two secondary windings that can be connected in series connection, according to some aspects of the present disclosure;

FIG. 3 is a schematic diagram of a connection of a transformer with configurable secondary windings and four switches, according to some aspects of the present disclosure;

FIG. 4 is a schematic diagram of an implementation of a transformer with configurable secondary windings using two DPDT relays and one driver, according to some aspects of the present disclosure;

FIG. 5A is a schematic diagram of an implementation of a transformer with at least two primary windings connected in series connection and one secondary winding, according to some aspects of the present disclosure;

FIG. 5B is a schematic diagram of an implementation of a transformer with at least two primary windings connected in parallel connection and one secondary winding, according to some aspects of the present disclosure;

FIG. 6 is a schematic diagram of an implementation of a transformer with configurable primary windings with four switches, according to some aspects of the present disclosure;

FIG. 7 is a schematic diagram of an implementation of a transformer with configurable primary windings using two DPDT relays and one driver, according to some aspects of the present disclosure;

FIG. 8A is a schematic diagram of an implementation of multiple transformers with a primary windings connected in parallel and secondary windings connected in parallel connection, according to some aspects of the present disclosure;

FIG. 8B is a schematic diagram of an implementation of multiple transformers with a primary windings connected in parallel and secondary windings connected in series connection, according to some aspects of the present disclosure;

FIG. 9A is a schematic diagram of an implementation of multiple transformers with a primary windings connected in series and secondary windings connected in parallel connection, according to some aspects of the present disclosure;

FIG. 9B is a schematic diagram of an implementation of multiple transformers with a primary windings connected in series and secondary windings connected in series connection, according to some aspects of the present disclosure;

FIG. 10A is a schematic diagram of an implementation of multiple transformers with configurable secondary switches connection using four switches when the primary windings are connected in parallel, according to some aspects of the present disclosure;

FIG. 10B is a schematic diagram of an implementation of multiple transformers with configurable secondary switches connection using four switches when the primary windings are connected in series, according to some aspects of the present disclosure;

FIG. 11A is a schematic diagram of an implementation of multiple transformers with configurable secondary switches connection using two DPDT relays and 1 driver when the primary windings are connected in parallel, according to some aspects of the present disclosure;

FIG. 11B is a schematic diagram of an implementation of multiple transformers with configurable secondary switches connection using two DPDT relays and 1 driver when the primary windings are connected in series, according to some aspects of the present disclosure;

FIG. 12A is a schematic diagram of an implementation of two paralleled transformers with a configurable secondary windings using two DPDT relays and 1 driver, according to some aspects of the present disclosure;

FIG. 12B is a schematic diagram of an implementation of two paralleled transformers with a configurable primary windings using two DPDT relays and 1 driver, according to some aspects of the present disclosure;

FIG. 13 is a schematic diagram of an implementation of four transformers with configurable secondary connections using six switches when the primary windings are connected in parallel, according to some aspects of the present disclosure;

FIG. 14 is a block diagram of an example computing device which may implement all or a portion of any component or functionality in FIGS. 1-12B and/or in FIGS. 13-14, according to some aspects of the present disclosure;

FIG. 15 is a flow diagram of an example method for controlling an alarm system, according to some aspects of the present disclosure.

### DETAILED DESCRIPTION

Various aspects are now described with reference to the drawings. In the following description, for purposes of explanation, numerous specific details are set forth in order to provide a thorough understanding of one or more aspects. It may be evident, however, that such aspect(s) may be practiced without these specific details.

Various aspects of the present disclosure provide a method, apparatus, and computer program for stepping up an amplifier output voltage to a required level using configurable transformer winding connections.

Audio notification appliance circuits (NACs) in alarm control panels (e.g., fire protection systems) usually use high signal voltage to reduce conduction power loss in the transmission wires. A typical voltage level of audio NACs are 25 Vᵣₘₛ or 70 Vᵣₘₛ (or more accurately 70.7 Vᵣₘₛ). It should be noted that 25 Vᵣₘₛ or 70 Vᵣₘₛ are commonly used in distributed audio design as field-selectable voltages and are understood by one of ordinary skill in the art to be approximate values.

Step-up transformers are generally the most common method of converting an amplifier output voltage to the desired voltage level. Typically, amplifier products with 25 Vᵣₘₛ or 70 Vᵣₘₛ voltage output levels have the same design and implementation with the exception that the output step-up transformers have different turns-ratio to obtain the required voltage levels. However, in the product development and accreditation processes, products with different output voltage levels need to be handled individually despite being almost identical in design. Therefore, the required resources and efforts spent on the amplifier products will be multiplied, which results in a significant increase in product development cost and time to market.

Wide-voltage-range amplifiers without the need of step-up transformer can solve the problem as the amplifier can be switched to either 25 Vᵣₘₛ or 70 Vᵣₘₛ. However, wide-voltage-range amplifiers requires an additional power supply with wide output voltage range from 60 V to 150 V, which significantly increases the manufacturing cost, power loss, size, and risk of EMI emission. In addition, the amplifier power stage needs high-voltage rating components (>150 V) that will incur additional power loss and cost.

Thus, there is a need for an improved process to match voltages to a desired voltage level while also a single product to provide different voltages and operate the amplifier power stage at low voltage levels. The present disclosure provides a method of using a low-cost and energy-efficient method to step up an amplifier output voltage to the required level using configurable transformer winding connections. In addition, with this method of using configurable transformer winding connections, only one product is needed to provide either 25 Vᵣₘₛ or 70 Vᵣₘₛ and the amplifier power stage can operate at low voltage levels so that it eliminates the need for extra resources for accrediting multiple products. Using only one product to accredit multiple products saves the product development cost and shortens the time to market.

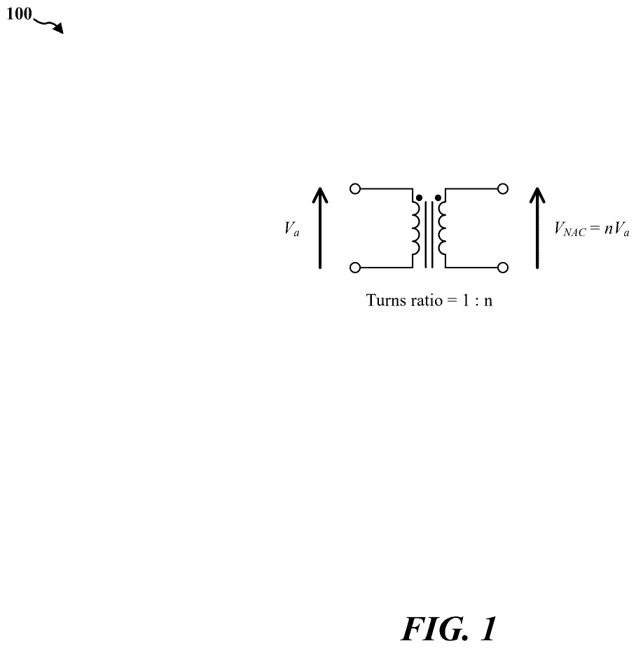

Referring to FIG. 1, in some embodiments of an audio NAC system, a step-up transformer 100 is used to match the output voltage of the power amplifier to the speaker voltage, in accordance with an example aspect. Specifically, the required turns-ratio of the set-up transformer is given by n=VNAC/Va, where n corresponds to the turn ratio, VNAC corresponds to the required output voltage, and Va is the amplifier output voltage For example, if the maximum voltage that the amplifier can deliver is 15 Vᵣₘₛ, and the required VNAC is 25 Vᵣₘₛ, the required turns-ratio of the step-up transformer is 1:25/15=1:1.67. In the case that the required NAC voltage is 70 Vᵣₘₛ, the turns ratio of the transformer would become 1:70/15=1:4.67.

As shown in FIG. 1, the output voltage of the step-up transformer 100 is determined by a transformer's turn-ratio, which is a fixed value. However, since the transformer's turn-ratio is a fixed value, this also means that the output voltage level is not configurable.

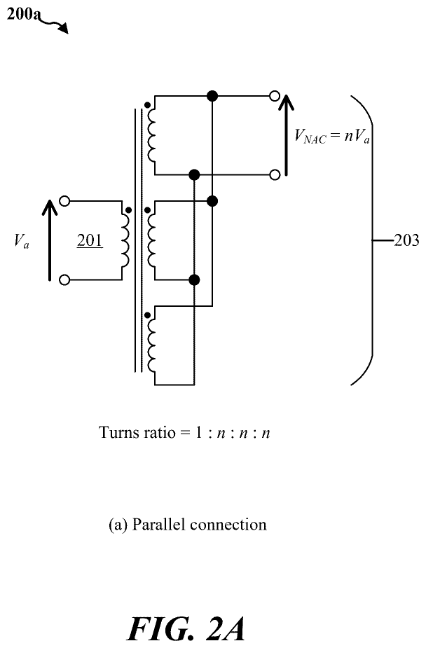

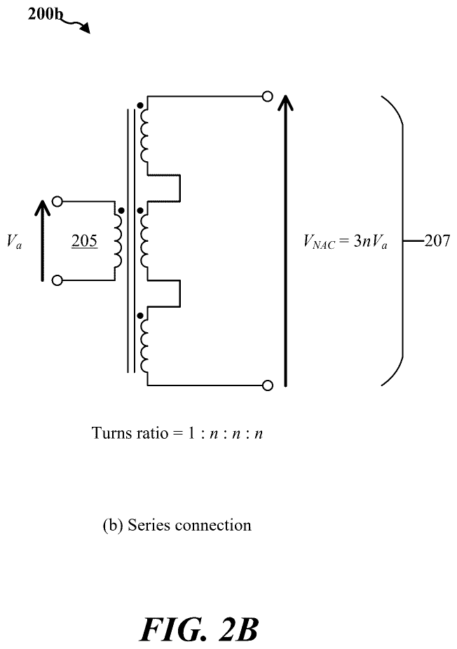

Referring to FIG. 2A an example of a schematic of the audio NAC system may be implemented on a printed circuit board (PCB) on an alarm panel. In some examples, the schematic of the audio NAC system is implemented as part of the alarm panel and/or part of a computing device is shown, in accordance with an exemplary aspect. Specifically, the example shows a transformer 200a with a primary winding 201 and at least two secondary windings 203 used to set the output NAC voltage to 25 Vᵣₘₛ.

When the required NAC voltage is 15 Vᵣₘₛ, all of the three secondary windings 203 have the same number of turns and the turns ratio is 1:1.67:1.67:1.67 and are connected in parallel.

Referring to FIG. 2B, an example of a schematic of the audio NAC system may be implemented on a printed circuit board (PCB) on an alarm panel. In some examples, the schematic of the audio NAC system is implemented as part of the alarm panel and/or part of a computing device is shown, in accordance with an example aspect. Specifically, the example shows a transformer 200b with a primary winding 205 and at least two secondary windings 207 used to set the output NAC voltage to 70 Vᵣₘₛ.

When the required NAC voltage is 70 Vᵣₘₛ, all of the three secondary windings 203 are connected in series such that the output voltage would be 3*1.67 times the amplifier voltage (e.g., 75 Vᵣₘₛ or 15 Vᵣₘₛ), which is 7% higher than the required voltage of 70Vᵣₘₛ. In this situation, the gain of the amplifier should be reduced by 7% so that the NAC voltage would become 70 Vᵣₘₛ. In addition, if the NAC voltage should be 70.7 Vᵣₘₛ, the amplifier gain should be further reduced by 6%.

In some examples, in the transformer design, the three secondary windings can be wounded individually around the core. In some examples, in the transformer design, the three secondary windings can be made by a multi-filar winding wire (e.g., a trifilar may have three wires bundled together, a bifilar has two wires bundled together, etc.) such that the electrical properties of the three windings would be practically identical or equivalent.

The parallel connection or series connection of the transformer windings may be configurable by using switches.

Similarly, in some embodiments of an audio NAC system and similar to FIGS. 2A and 2B, a step-down transformer may also be used to match output voltages in the case when the amplifier voltage is higher than the NAC voltage. In this case, the turns ratio n may be less than 1.

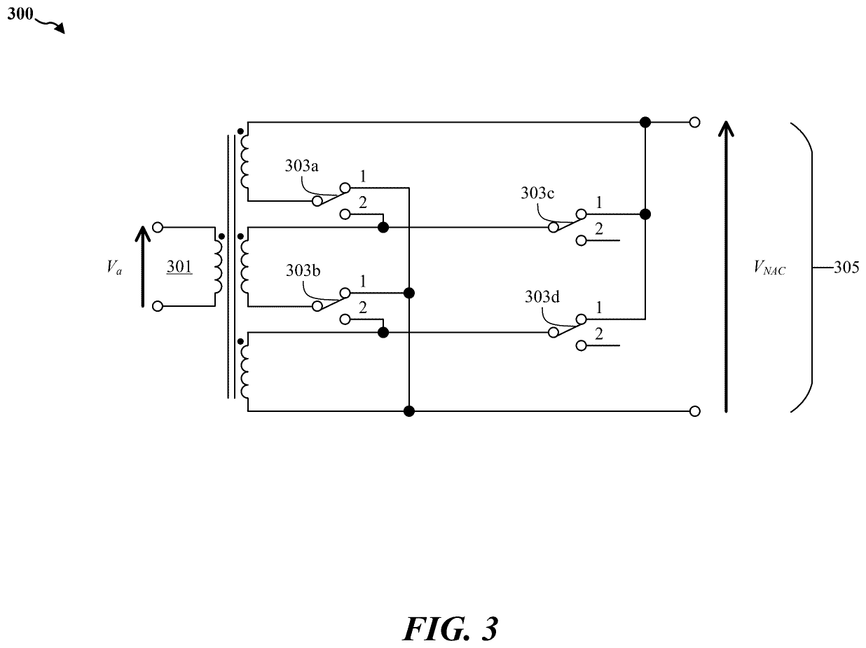

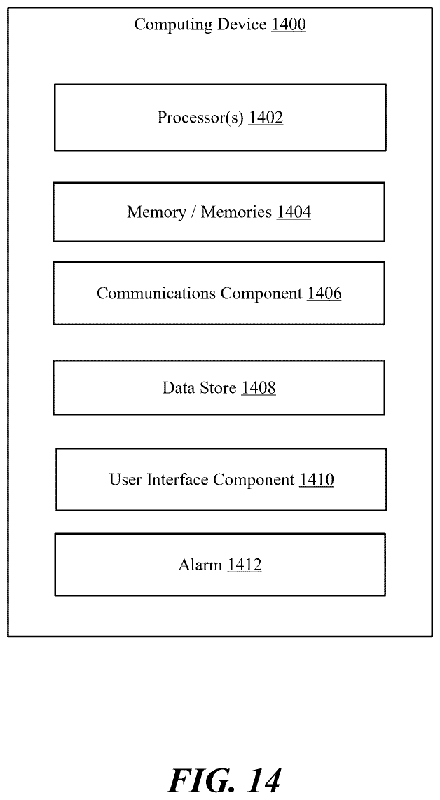

Referring to FIG. 3, is an example of a schematic diagram of a connection of a transformer with a primary winding 301, configurable secondary windings 305 and four switches 303a, 303b, 303c, 303d. The schematic diagram of the connection of the transformer with the primary winding 301, configurable secondary windings 305 and four switches 303a, 303b, 303c, 303d may be implemented on a PCB on an alarm panel and/or part of a computing device (computing device 1400 as shown in FIG. 14), in accordance with an exemplary aspect.

Specifically, as shown in the transformer 300, when all the switches 303a, 303b, 303c, 303d are in position 1, all the three secondary windings 305 will be connected in parallel so the output NAC voltage will be 25 Vᵣₘₛ. When all the switches 303a, 303b, 303c, 303d are in position 2 and the amplifier gain is adjusted by 7%, the secondary windings will be in series connection and the output NAC voltage would become 70 Vᵣₘₛ. In some examples, the switches 303a, 303b, 303c, 303d can be implemented with manual mechanical switches or jumpers such that the output voltage can be selected manually. In some examples, the switches 303a, 303b, 303c, 303d can be implemented with mechanical or solid-state relays, then the output voltage can be configured by an electrical circuit, a micro controller, or a computing device such as or any other device or devices that may provide output voltages.

As shown in FIG. 3, the four switches can be individual switches 303a, 303b, 303c, 303d or relays. In some examples, the four switches 303a, 303b, 303c, 303d can be implemented as at least one double-pole-double-throw (DPDT) switch or relay. In some examples, the four switches 303a, 303b, 303c, 303d can be implemented as a single 4-pole-double-throw switch, where each switch has two positions (e.g., two throws) to select or relay.

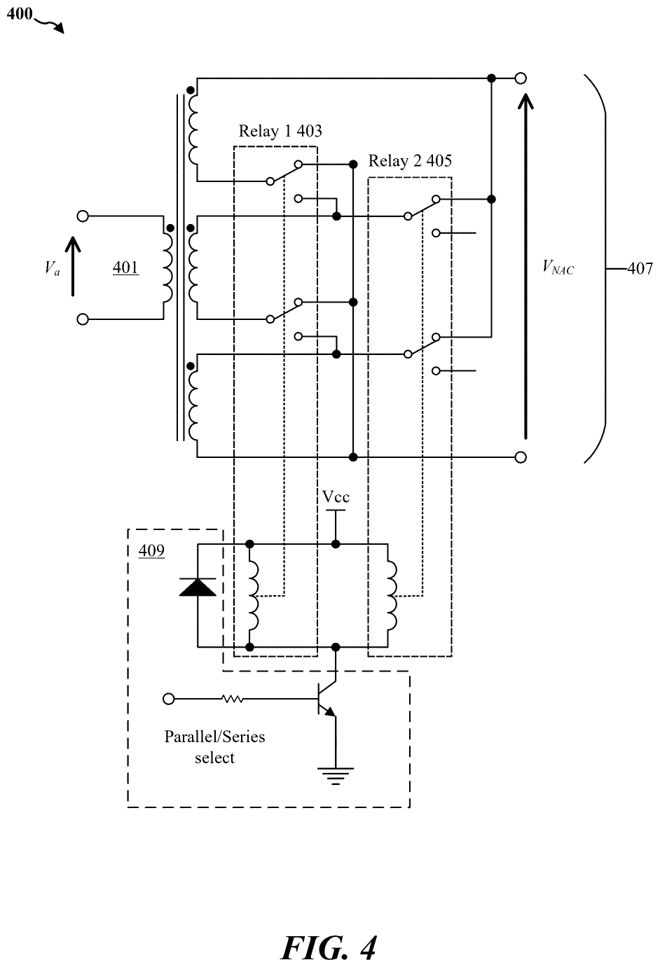

Referring to FIG. 4, is an example of a schematic diagram of a connection of a configurable transformer with two DPDT relay and a single driver. The schematic diagram of a connection of a configurable transformer with two DPDT relay and a single driver may be implemented on a PCB on an alarm panel and/or part of a computing device (computing device 1400 as shown in FIG. 14), in accordance with an exemplary aspect.

As shown in FIG. 4, the transformer 400 has a primary winding 401, three configurable secondary windings 407 that are connected by two DPDT relays 403, 405. In addition, the two DPDT relays 403, 405 uses a single driver in order to connect the three configurable secondary windings 407 in series connection or parallel connection. Specifically, the transformer 400 has a driver 409 of the relay coil, which is part of the relay device. The relay coil is an electromagnet that is used in a relay to control the switching of electrical circuits (e.g., selection of a parallel connection or a series connection).

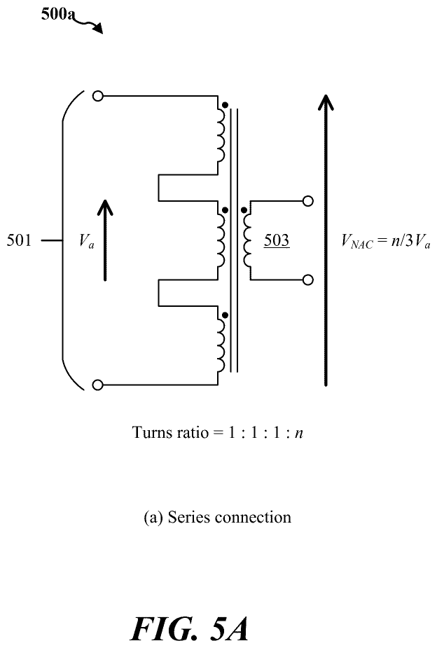

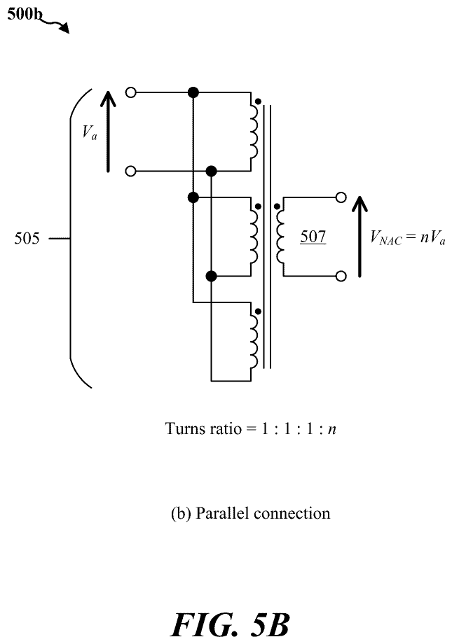

Referring to FIG. 5A, is an example of a schematic diagram of an implementation of a transformer with at least two primary windings connected in series and one secondary winding. The schematic diagram of an implementation of a transformer with at least two primary windings connected in series and one secondary winding may be implemented on a PCB on an alarm panel and/or part of a computing device (computing device 1400 as shown in FIG. 14), in accordance with an exemplary aspect.

As compared to FIGS. 2-4, FIG. 5A shows a transformer with multiple primary windings and a single secondary winding in series connection or parallel connection. Alternatively, as shown in FIG. 5A, a transformer with multiple primary windings and a single secondary winding can also be used to obtain different output voltage levels depending on whether the multiple primary windings are connected in series connection or parallel connection. However, the turns ratios will be different from the previous transformers in FIGS. 2-4.

FIG. 5A shows a transformer 500a with at least two primary windings 501 connected in series and a secondary winding 503. Specifically, when the primary windings 501 are connected in series, the output voltage will be n/3 times of the amplifier output voltage (i.e., VNAC=n/3 Va). If the amplifier output voltage Va is 15 Vᵣₘₛ and the required output NAC voltage is 25 Vᵣₘₛ, then the turns ratio should be n=25/15*3=5.

Referring to FIG. 5B, is an example of a schematic diagram of an implementation of a transformer 500b with at least two primary windings 505 connected in parallel and a secondary winding 507. The schematic diagram of an implementation of a transformer with three primary windings connected in parallel and one secondary winding may be implemented on a PCB on an alarm panel and/or part of a computing device (computing device 1400 as shown in FIG. 14), in accordance with an exemplary aspect.

Specifically, when the three primary windings 505 are connected in parallel, the output voltage will be 5 times the amplifier voltage (i.e., VNAC=5*15=75 Vᵣₘₛ). In addition, the voltage gain of the amplifier may be reduced by 7% such that the required output NAC voltage of 70 Vᵣₘₛ can be obtained.

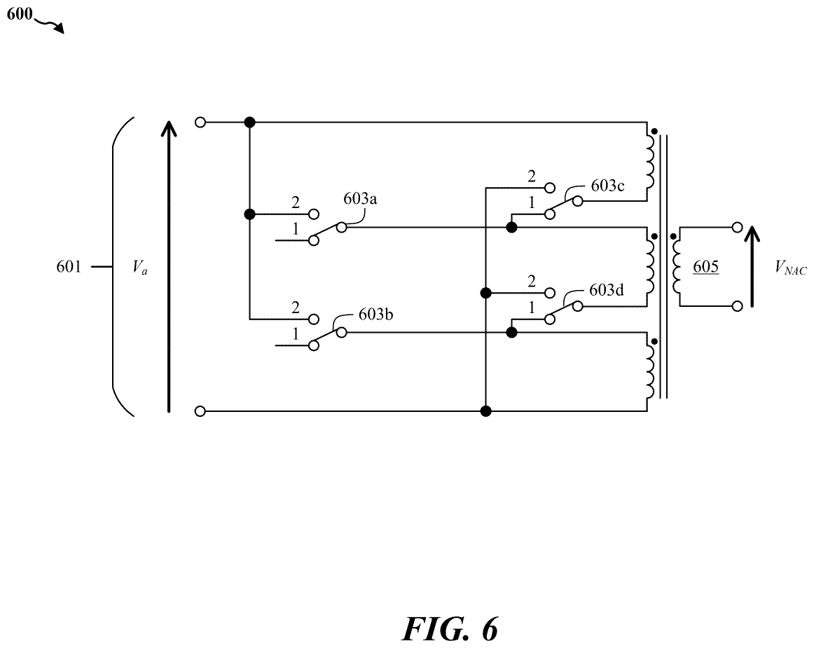

Referring to FIG. 6, is an example of a schematic diagram of an implementation of a configurable transformer 600 with a single secondary winding 605 and configurable primary windings with four switches. The schematic diagram of an implementation of a configurable transformer 600 with a single secondary winding 605 and configurable primary windings with four switches may be implemented on a PCB on an alarm panel and/or part of a computing device (computing device 1400 as shown in FIG. 14), in accordance with an exemplary aspect.

Similar to the configurable transformer 300 from FIG. 3, when all of the switches 603a, 603b, 603c, 603d of the configurable transformer 600 are in position 1, all the three primary windings 601 are connected in series so the output NAC voltage is 25 Vrms. When the switches 603a, 603b, 603c, 603d are in position 2 and the amplifier gain is adjusted down by 7%, the three primary windings 601 will be in parallel connection and the output NAC voltage will become 70 Vᵣₘₛ. In some examples, the switches 603a, 603b, 603c, 603d can be implemented with manual mechanical switches or jumpers such that the output voltage levels can be selected manually. In some examples, the switches 603a, 603b, 603c, 603d can be implemented with mechanical or solid-state relays such that the output voltage can be configured by an electronic circuit, a microcontroller, or a computer in response to a command from a user or user interface. In some examples, a user may select a first voltage or second voltage via a user interface (e.g., user interface component 1410) and then send the command to an alarm (e.g., audible alarm 1412).

In some examples, the four switches 603a, 603b, 603c, 603d can be four individual switches 603a, 603b, 603c, 603d or relays. In some examples, the four switches 603a, 603b, 603c, 603d can be two DPDT switches or relays. In some examples, the four switches 603a, 603b, 603c, 603d can be one 4-pole-double-throw switch or relay.

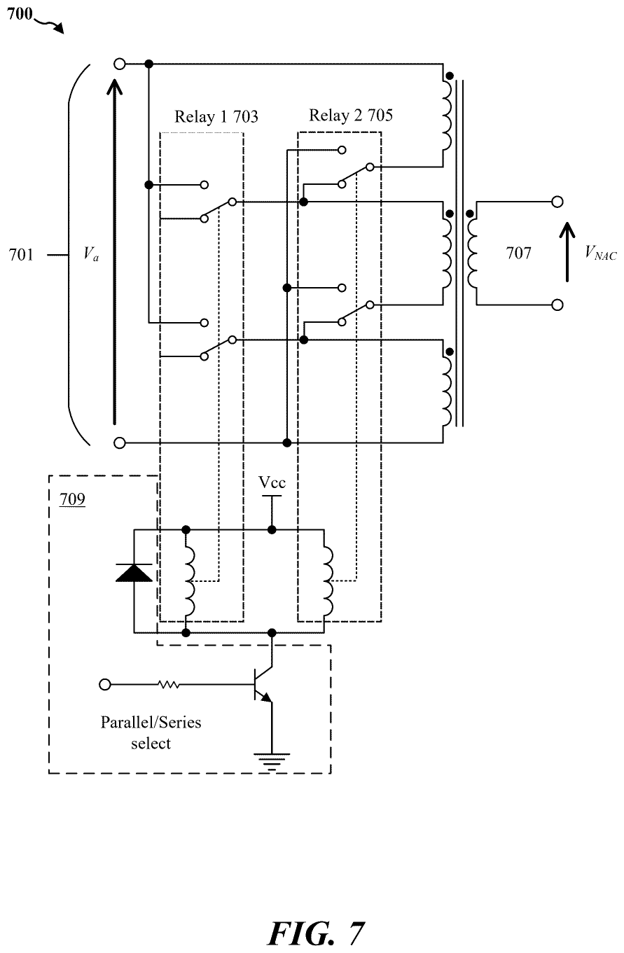

Referring to FIG. 7, is an example of a schematic diagram of an implementation of a transformer with configurable primary windings using two DPDT relays and one driver, according to some aspects of the present disclosure. The schematic diagram of an implementation of a transformer with configurable primary windings using two DPDT relays and one driver, according to some aspects of the present disclosure may be implemented on a PCB on an alarm panel and/or part of a computing device (computing device 1400 as shown in FIG. 14), in accordance with an exemplary aspect.

Unlike the transformer 400 in FIG. 4, the transformer 700 has three configurable primary windings 701, and a secondary winding 707 that are connected by two DPDT relays 703, 705. In addition, the two DPDT relays 703, 705 uses a single driver in order to connect the three configurable secondary windings 707 in series or parallel. Specifically, the transformer 700 has a driver 709 of the relay coil, which is part of the relay device.

Multiple Transformers with a Single Primary Winding and a Single Secondary Winding

In addition to using a transformer with multiple primary windings (e.g., FIGS. 4-6) or multiple secondary windings (e.g., FIGS. 2-3 and 7), multiple transformers with a single primary winding and a single secondary winding can be used to set the output NAC to the required voltage.

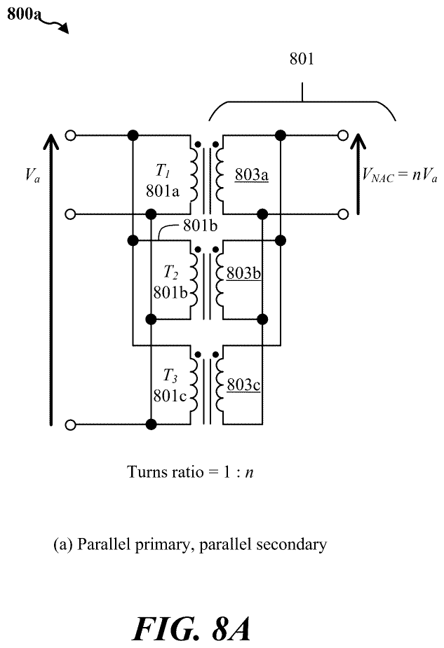

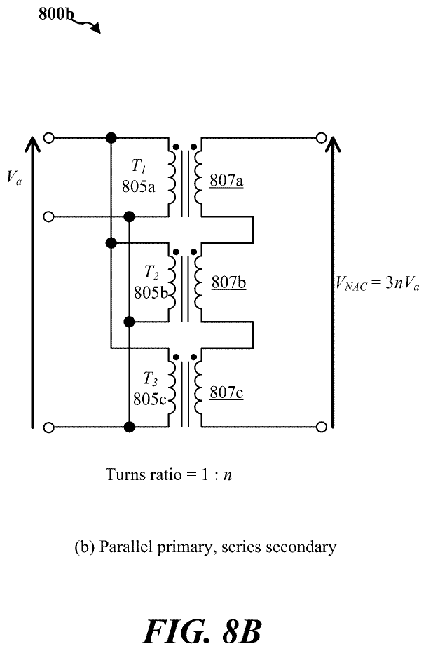

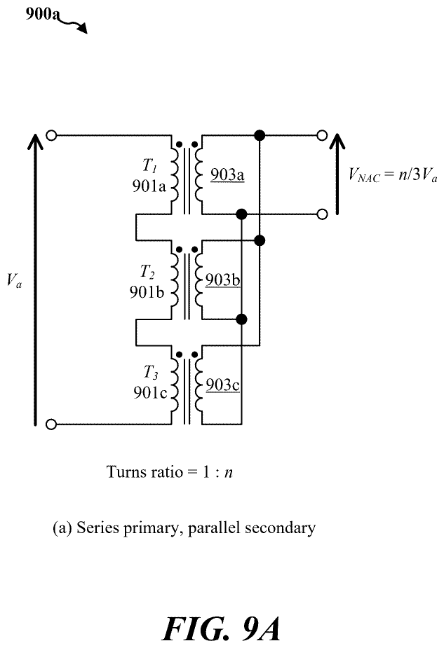

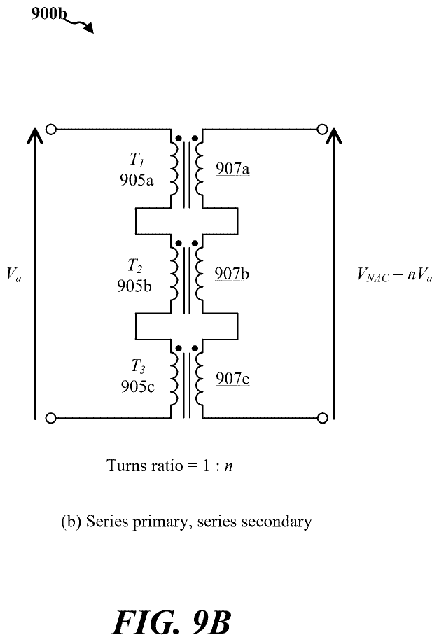

FIGS. 8A-9B illustrate different connections of using at least two transformers with a single primary winding and a single secondary winding. All of the at least two transformers have same turns ratios. The advantage of using multiple transformers is that the heat dissipation can be spread over a larger volume and the power capability of the circuit is multiplied by the number of transformers.

Referring to example 800a of FIG. 8A, is an example of a schematic diagram of an implantation of multiple transformers 801a, 801b, 801c with a primary winding connected in parallel and secondary windings connected in parallel. The schematic diagram of an implantation of multiple transformers 801a, 801b, 801c with a primary winding connected in parallel and secondary windings connected in parallel may be implemented on a PCB on an alarm panel and/or part of a computing device (computing device 1400 as shown in FIG. 14), in accordance with an exemplary aspect.

Specifically, as shown in example 800a of FIG. 8, if the amplifier output voltage is 15 Vᵣₘₛ and the required output NAC voltage is 25 Vᵣₘₛ, and the secondary windings 803a, 803b, 803c are connected in parallel, then the required turns ratio should be 1:25/15=1:1.67.

Referring to example 800b of FIG. 8B, is an example of schematic diagram of an implementation of multiple transformers 805a, 805b, 805c with primary windings connected in parallel and secondary windings 807a, 807b, 807c connected in series. The schematic diagram of an implantation of multiple transformers 805a, 805b, 805c with primary windings connected in parallel and secondary windings 807a, 807b, 807c connected in series may be implemented on a PCB on an alarm panel and/or part of a computing device (computing device 1400 as shown in FIG. 14), in accordance with an exemplary aspect.

Specifically, as shown in the example 800b of FIG. 8B, when the required output NAC voltage is 70 Vᵣₘₛ, then all of the at least two transformers' secondary windings 807a, 807b, 807c are connected in series so that the output voltage would be 3*1.67 times of the amplifier output voltage (i.e., 75 Vᵣₘₛ, which is 7% higher than the required voltage of 70 Vᵣₘₛ). Since the output voltage is 7% higher than the required voltage of 70 Vᵣₘₛ, the gain of the amplifier should be reduced by 7% so that the output NAC voltage would become 70 Vᵣₘₛ.

The primary windings of the transformers can also be connected in series to obtain the required output NAC voltage as shown below in FIG. 9A. Compared to the transformers in FIG. 8, the turns ratio of the transformers in FIG. 9A is different.

Referring to example 900a of FIG. 9A, is an example of schematic diagram of an implementation of multiple transformers with primary windings connected in series and secondary windings connected in parallel. The schematic diagram of an implementation of multiple transformers with primary windings connected in series and secondary windings connected in parallel may be implemented on a PCB on an alarm panel and/or part of a computing device (computing device 1400 as shown in FIG. 14), in accordance with an exemplary aspect.

Specifically, as shown in example 900a of FIG. 9A, the amplifier output voltage is set to 15 Vᵣₘₛ. If the required output NAC is 25 Vᵣₘₛ, then the three transformer's 901a, 901b, 901c secondary windings 903a, 903b, 903c should be connected in parallel and the required turns ratio should be 1:3*25/15=1:5.

Referring to example 900b of FIG. 9B, is an example of schematic diagram of an implementation of multiple transformers with primary windings connected in series and secondary windings connected in series. The schematic diagram of an implementation of multiple transformers with primary windings connected in series and secondary windings connected in series may be implemented on a PCB on an alarm panel and/or part of a computing device (computing device 1400 as shown in FIG. 14), in accordance with an exemplary aspect.

As shown in FIG. 9B, when the required NAC voltage is 70 Vᵣₘₛ, all the three transformers' 905a, 905b, 905c secondary windings 907a, 907b, 907c should be connected in series so that the output voltage will be 5 times of the amplifier voltage (i.e., 75 Vᵣₘₛ, which is 7% higher than the required voltage of 70 Vᵣₘₛ). In this situation, the gain of the amplifier should be reduced by 7% so that the output NAC voltage would become 70 Vᵣₘₛ.

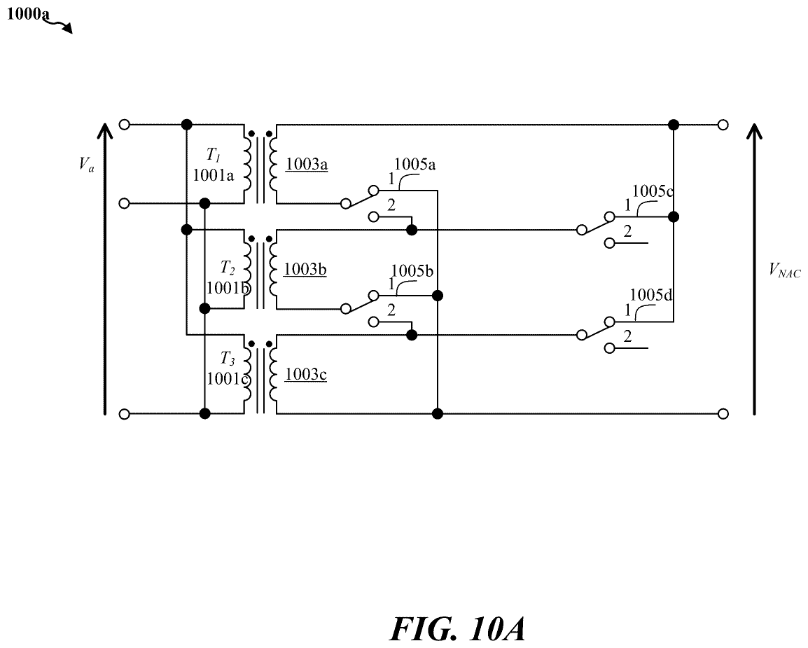

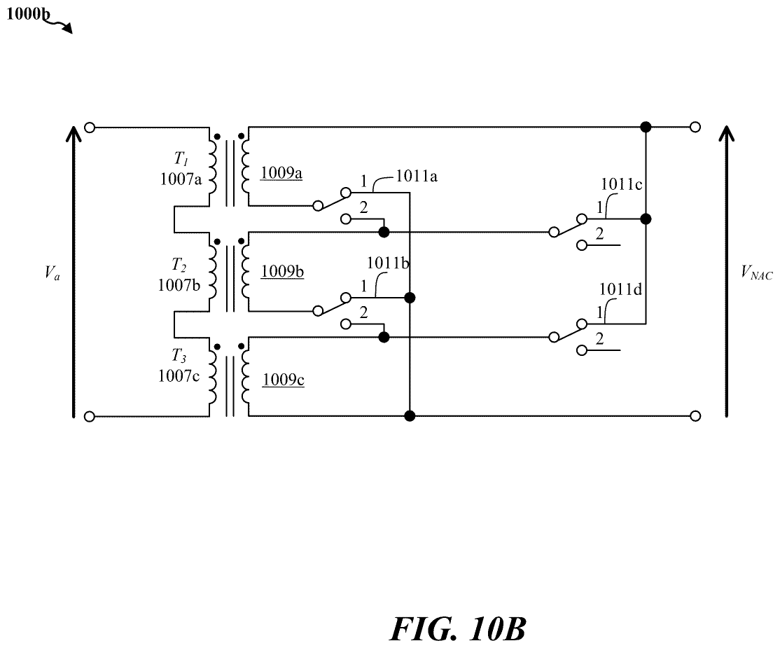

Like the single transformer with multiple primary or secondary windings, the connection of multiple transformers with a single primary winding and a single secondary winding can be configurable using switches to obtain the required output voltage level as shown in FIGS. 10A-10B. Please note that the connection type of the primary windings determines the turns ratio. As addressed previously, if the amplifier output voltage is 15 Vᵣₘₛ and the desired output voltage levels are 25 Vᵣₘₛ or 70 Vᵣₘₛ, the required transformer turns ratio for parallel and series primary winding connections should be 1:1.67 and 1:5, respectively.

Referring to example 1000a of FIG. 10A, is a schematic diagram of an implementation of multiple transformers with configurable secondary switches connection using four switches when the primary windings are connected in parallel. The schematic diagram of an implementation of multiple transformers with configurable secondary switches connection using four switches when the primary windings are connected in parallel may be implemented on a PCB on an alarm panel and/or part of a computing device (computing device 1400 as shown in FIG. 14), in accordance with an exemplary aspect.

When all the switches 1005a, 1005b, 1005c, 1005d of the multiple transformers 1001a, 1001b, 1001c are in position 1, all the three secondary windings 1003a, 1003b, 1003c are connected in parallel so the output NAC voltage will be 25 Vᵣₘₛ.

In some examples, the switches 1005a, 1005b, 1005c, 1005d can be implemented with manual mechanical switches or jumpers so that the output voltage levels can be selected manually. In some examples, the switches 1005a, 1005b, 1005c, 1005d can be implemented with mechanical or solid-state relays, then the output voltage can be configured by an electronic circuit, a microcontroller, or a controller in response to a command from a user or user interface. In some examples, a user may select a first voltage or second voltage via a user interface (e.g., user interface component 1410) and then send the command to an alarm (e.g., audible alarm 1412).

Referring to example 1000b of FIG. 10B, is a schematic diagram of an implementation of multiple transformers 1007a, 1007b, 1007c with configurable secondary windings 1009a, 1009b, 1009c connection using four switches 1011a, 1011b, 1011c, 1011d when the primary windings are connected in series. The schematic diagram of an implementation of multiple transformers 1007a, 1007b, 1007c with configurable secondary windings 1009a, 1009b, 1009c connection using four switches 1011a, 1011b, 1011c, 1011d when the primary windings are connected in series may be implemented on a PCB on an alarm panel and/or part of a computing device (computing device 1400 as shown in FIG. 14), in accordance with an exemplary aspect.

When the switches 1011a, 1011b, 1011c, 1011d are in position 2 and the amplifier gain is adjusted down by 7%, the configurable secondary windings 1009a, 1009b, 1009c will be in series connection and the output NAC voltage would be 70 Vᵣₘₛ.

When the switches 1011a, 1011b, 1011c, 1011d are in position 1, the configurable secondary windings 1009a, 1009b, 1009c will be in parallel connection and the output NAC voltage would be 25 Vᵣₘₛ.

In some examples, the switches 1011a, 1011b, 1011c, 1011d can be implemented with manual mechanical switches or jumpers so that the output voltage levels can be selected manually. In some examples, the switches 1011a, 1011b, 1011c, 1011d can be implemented with mechanical or solid-state relays, then the output voltage can be configured by an electronic circuit, a microcontroller, or a controller in response to a command from a user or user interface.

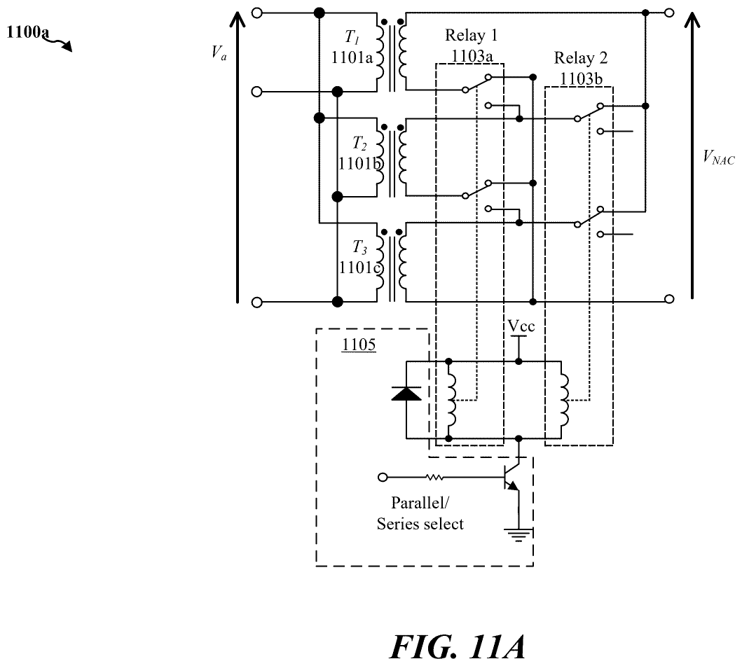

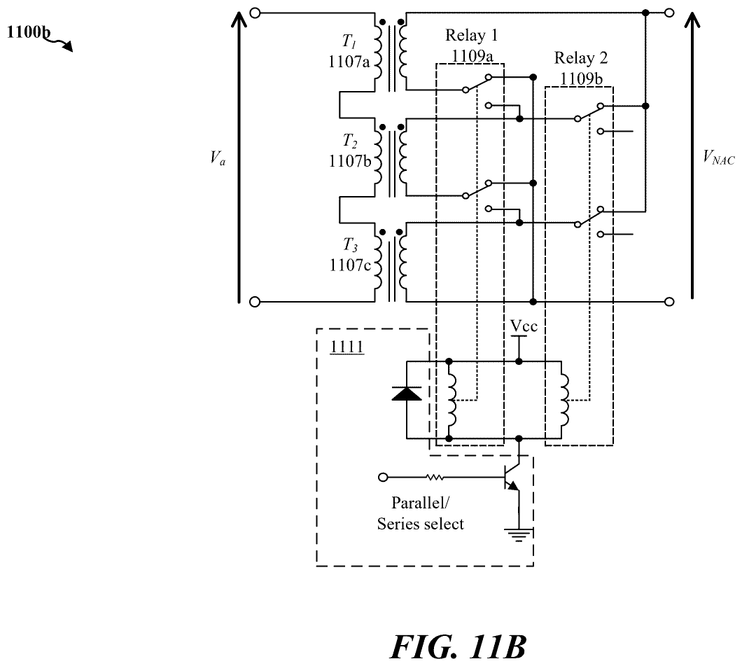

Referring to example 1100a of FIG. 11A, is a schematic diagram of an implementation of multiple transformers with configurable secondary switches connection using two DPDT relays and 1 driver when the primary windings are connected in parallel. The schematic diagram of an implementation of multiple transformers with configurable secondary switches connection using two DPDT relays and 1 driver when the primary windings are connected in parallel may be implemented on a PCB on an alarm panel and/or part of a computing device (computing device 1400 as shown in FIG. 14), in accordance with an exemplary aspect.

Specifically, example 1100a of FIG. 11A shows an example of configurable transformers 1101a, 1101b, 1101c with two DPDT relays 1103a, 1103b, which only requires a single driver. Specifically, example 1100a shows a driver 1105 of the relay coil, which is part of the relay device.

Referring to example 1100b of FIG. 11B is a schematic diagram of an implementation of multiple transformers with configurable secondary switches connection using two DPDT relays and 1 driver when the primary windings are connected in series. The schematic diagram of an implementation of multiple transformers with configurable secondary switches connection using two DPDT relays and 1 driver when the primary windings are connected in series may be implemented on a PCB on an alarm panel and/or part of a computing device (computing device 1400 as shown in FIG. 14), in accordance with an exemplary aspect.

Specifically, example 1100b of FIG. 11B shows an example of configurable transformers 1107a, 1107b, 1107c with two DPDT relays 1109a, 1109b, which only requires a single driver. Specifically, example 1100b shows a driver 1111 of the relay coil, which is part of the relay device.

### Increase of Power Capability by Connecting Multiple Identical Transformers in Parallel

In applications, if one transformer is not sufficient to provide the required output power, multiple identical transformers can be connected in parallel to deliver more power to the load.

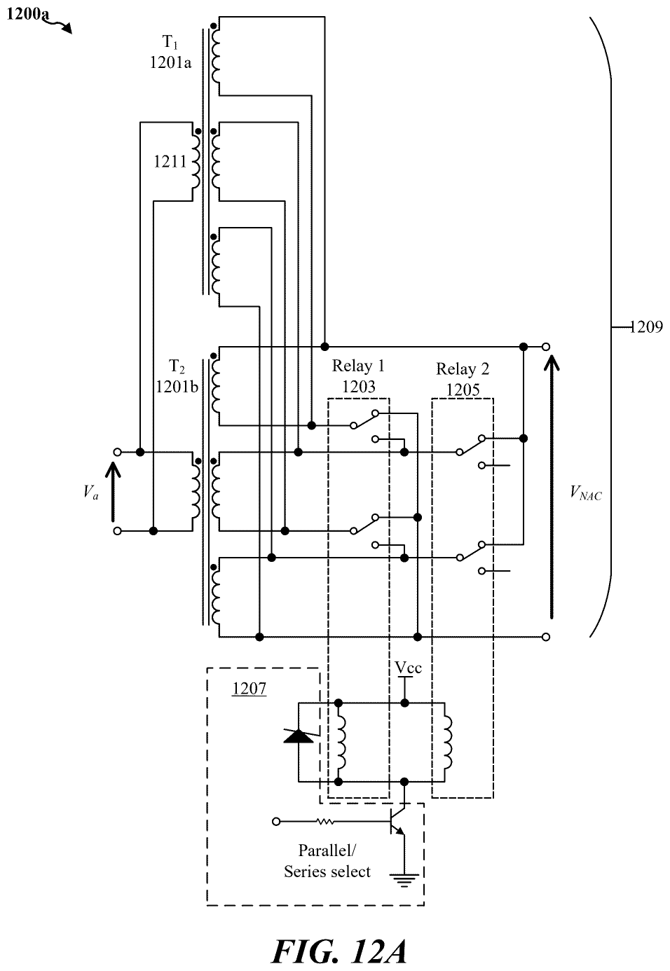

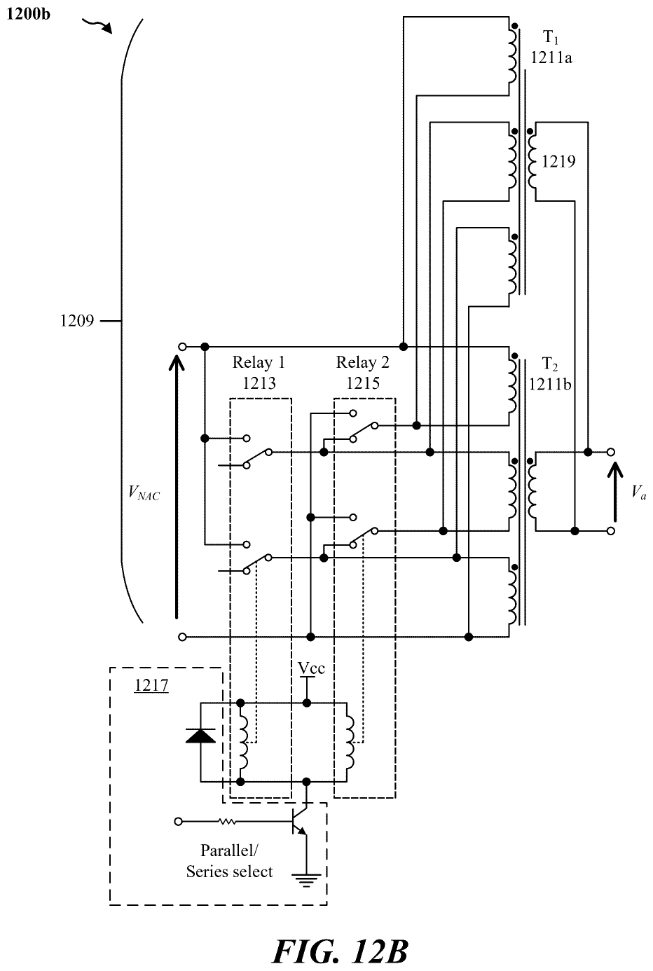

Referring to example 1200a of FIG. 12A is a schematic diagram of an implementation of two paralleled transformers 1201a, 1201b with a configurable secondary windings 1209 using at least one DPDT relay 1203, 1205, a relay circuit and a single driver. Specifically, example 1200a shows a driver 1207 of the relay coil, which is part of the relay device. The schematic diagram of an implementation of two paralleled transformers 1201a, 1201b with a configurable secondary windings 1209 using two DPDT relays 1203, 1205, a relay circuit and a single driver may be implemented on a PCB on an alarm panel and/or part of a computing device (computing device 1400 as shown in FIG. 14), in accordance with an exemplary aspect.

Specifically, example 1200a of FIG. 12A shows an example of connecting two identical transformers 1201a, 1201b with a single primary winding 1211 and at least two secondary windings 1209 in parallel. Although two transformers 1201a, 1201b are used, the same relay circuit can be used and it is not necessary to increase the number of relays 1203, 1205 as long as the power ratings of the relays 1203, 1205 are high enough to handle the combined output power of the two transformers 1201a, 1201b.

Referring to example 1200b of FIG. 12B, is a schematic diagram of an implementation of two paralleled transformers 1211a, 1211b with at least two configurable primary windings 1209 using at least one DPDT relays 1213, 1215, relay circuit and a single driver. Specifically, example 1200b shows a driver 1217 of the relay coil, which is part of the relay device. The schematic diagram of an implementation of two paralleled transformers 1211a, 1211b with a configurable primary windings 1209 using two DPDT relays 1213, 1215, relay circuit and a single driver may be implemented on a PCB on an alarm panel and/or part of a computing device (computing device 1400 as shown in FIG. 14), in accordance with an exemplary aspect.

Specifically, example 1200b of FIG. 12B shows an example of connecting two identical transformers 1211a, 1211b with three primary windings 1209 and a single secondary windings 1219 in parallel to double the power capability.

Different Output Voltage Levels with Different Number of Transformers and Windings

In the previous example described above, the output voltage levels were set to 25 Vᵣₘₛ or 70 Vᵣₘₛ, and the number of windings connected in parallel or in series is three. However, it should be noted that the output voltage levels of 25 Vᵣₘₛ or 70 Vᵣₘₛ and the number of windings connected in parallel or in series is three are used for illustrative purposes only. It should be noted that the present disclosure may describe any two output voltage levels with a corresponding number of windings connected in parallel or in series.

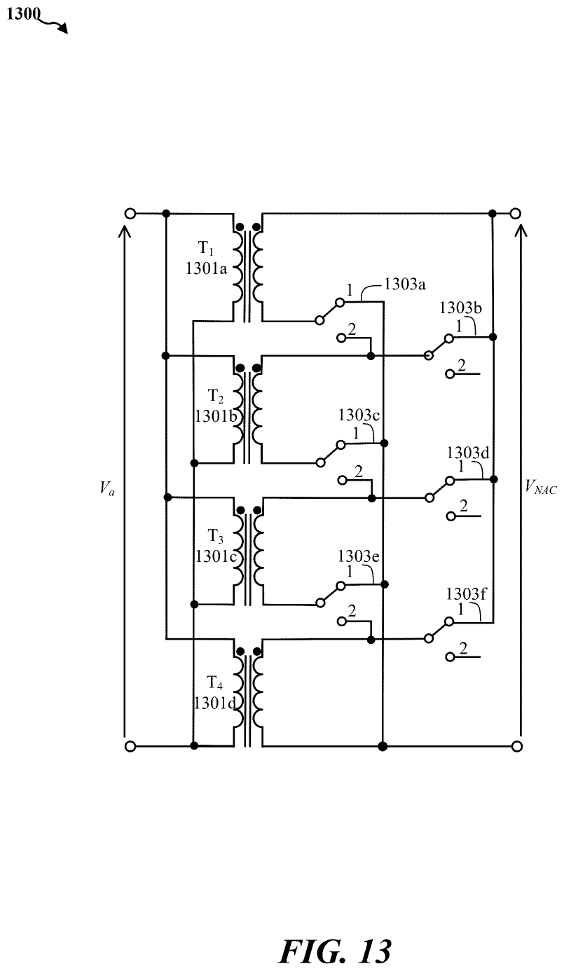

Referring to example 1300 of FIG. 13, is a schematic diagram of an implementation of four transformers 1301a, 1301b, 1301c, 1301d with configurable secondary connections using six switches 1303a, 1303b, 1303c, 1303d, 1303e, 1303f when the primary windings are connected in parallel. The schematic diagram of an implementation of four transformers 1301a, 1301b, 1301c, 1301d with configurable secondary connections using six switches 1303a, 1303b, 1303c, 1303d, 1303e, 1303f when the primary windings are connected in parallel may be implemented on a PCB on an alarm panel and/or part of a computing device (computing device 1400 as shown in FIG. 14), in accordance with an exemplary aspect.

As an example, in example 1300 of FIG. 13, the connection of the transformer circuit may obtain an output NAC voltage of 25 Vᵣₘₛ or 100 Vᵣₘₛ. The required number of transformers or number of configurable windings is four because the high-to-low NAC voltage ratio is 100/25=4.

Specifically, in example 1300 of FIG. 13 four transformers 1301a, 1301b, 1301c, 1301d with a single primary winding and a single secondary winding are used. Alternatively, a transformer with four primary windings or four secondary windings can also be used. The required number of switches is proportional to the number of transformers used. In this example 1300, six switches 1303a, 1303b, 1303c, 1303d, 1303c, 1303f are required. Here, the amplifier output voltage may be the same as in the previous examples (i.e., 15 Vᵣₘₛ) so that the required turns ratio of the transformer is 1:1.67. When the switches are in position 1, all the transformer's secondary windings are connected in parallel, then the output NAC voltage would be 15*1.67=25 Vᵣₘₛ. When the switches are in position 2, the secondary windings would be in series connection, then the output voltage would be 4*15*1.67=100 Vᵣₘₛ.

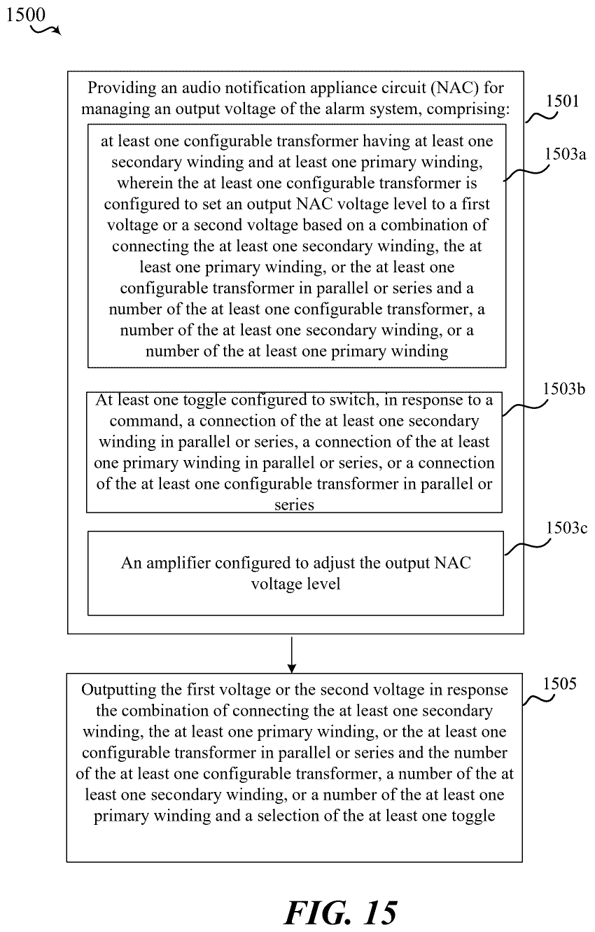

Referring to FIG. 14, a computing device 1400 may implement all or a portion of the functionality described in FIGS. 1-14 above or described in FIG. 15 below. For example, the computing device 1400 may be or may include at least a portion of a configurable transformer, a toggle, or an amplifier or any of the components described herein with reference to FIGS. 1-14 above. The computing device 1400 includes a processor 1402 which may be configured to execute or implement software, hardware, and/or firmware modules that perform any functionality described herein with reference to FIGS. 1-14 above or with reference to FIG. 15 below. For example, the processor 1402 may be configured to execute or implement software, hardware, and/or firmware modules that perform any functionality described herein with reference to the configurable transformer, a toggle, or an amplifier or any other component, system, device described herein with reference to FIGS. 1-14 above.

The processor 1402 may be a micro-controller, an application-specific integrated circuit (ASIC), or a field-programmable gate array (FPGA), and/or may include a single or multiple set of processors or multi-core processors. Moreover, the processor 1402 may be implemented as an integrated processing system and/or a distributed processing system. The computing device 1400 may further include a memory 1404, such as for storing local versions of applications being executed by the processor 1402, related instructions, parameters, etc. The memory 1404 may include a type of memory usable by a computer, such as random access memory (RAM), read only memory (ROM), tapes, magnetic discs, optical discs, volatile memory, non-volatile memory, and any combination thereof. Additionally, the processor 1402 and the memory 1404 may include and execute an operating system executing on the processor 1402, one or more applications, display drivers, etc., and/or other components of the computing device 1400.

Further, the computing device 1400 may include a communications component 1406 that provides for establishing and maintaining communications with one or more other devices, parties, entities, etc. utilizing hardware, software, and services. The communications component 1406 may carry communications between components on the computing device 1400, as well as between the computing device 1400 and external devices, such as devices located across a communications network and/or devices serially or locally coupled with the computing device 1400. In an aspect, for example, the communications component 1406 may include one or more buses, and may further include transmit chain components and receive chain components associated with a wireless or wired transmitter and receiver, respectively, operable for interfacing with external devices.

Additionally, the computing device 1400 may include a data store 1408, which can be any suitable combination of hardware and/or software, that provides for mass storage of information, databases, and programs. For example, the data store 1408 may be or may include a data repository for applications and/or related parameters not currently being executed by processor 1402. In addition, the data store 1408 may be a data repository for an operating system, application, display driver, etc., executing on the processor 1402, and/or one or more other components of the computing device 1400.

The computing device 1400 may also include a user interface component 1410 operable to receive inputs from a user of the computing device 1400 and further operable to generate outputs for presentation to the user (e.g., via a display interface to a display device). In some examples, the user interface component 1410 may receive a selection of a first voltage output or a second voltage output from a user. The user interface component 1410 may include one or more input devices, including but not limited to a keyboard, a number pad, a mouse, a touch-sensitive display, a navigation key, a function key, a microphone, a voice recognition component, or any other mechanism capable of receiving an input from a user, or any combination thereof. Further, the user interface component 1410 may include one or more output devices, including but not limited to a display interface, a speaker, a haptic feedback mechanism, a printer, any other mechanism capable of presenting an output to a user, or any combination thereof.

The computing device 1400 may also include an audible alarm 1412 configured to generate an audible signal.

FIG. 15 is a flowchart of a method 1500 of operation of the computing device 1400. The method 1500 may implement the functionality described herein with reference to FIGS. 1-14 above and may be performed by one or more components of the computing device 1400 or any device/component described with reference to FIGS. 1-14 above.

At block 1501, the method 1500 includes providing an audio NAC for managing an output voltage of the alarm system.

Specifically, the method 1500 further include: providing, at block 1503a, at least one configurable transformer having at least one secondary winding and at least one primary winding, wherein the at least one configurable transformer is configured to set an output NAC voltage level to a first voltage or a second voltage based on a combination of connecting the at least one secondary winding, the at least one primary winding, or the at least one configurable transformer in parallel connection or series connection and a number of the at least one configurable transformer, a number of the at least one secondary winding, or a number of the at least one primary winding.

In some examples, the at least one secondary winding comprises at least three secondary winding each having a same number of turns and is configured to be wounded individually around a core of the at least one configurable transformer. In some examples, the at least one secondary winding comprises at least three secondary winding each having a same number of turns and is configured to be made by a multifilar winding wire such that electrical properties of each of the at least one secondary winding is identical.

As an example, referring back to FIGS. 2A-B, the one configurable transformer 200a has at least two secondary windings 203 and one primary winding 201 and the amplifier output voltage is 15 Vrms such that the one configurable transformer 200a is configured to set an output NAC voltage level to 25 Vrms based on connecting the at least two secondary windings 203 in parallel (e.g., transformer 200a) or to set the output NAC voltage level to 70 Vrms based on connecting the at least two secondary windings 207 in series (e.g., transformer 200b).

As an example, referring back to FIGS. 5A-B, the one configurable transformer has one secondary winding 503 and three primary windings 501 such that when the three primary windings 501 are connected in series, the output voltage will be n/3 times of the amplifiers output voltage (i.e., VNAC=n/3 Va), as shown in the transformer 500a, and when the three primary windings 505 are connected in parallel, the output voltage will be n times of the amplifier voltage (i.e., VNAC=n*Va), as shown in the transformer 500b.

In some examples, the at least one primary winding comprises at least three primary windings and is configured to be wounded individually around a core of the at least one configurable transformer. In some examples, the at least one primary winding comprises at least three primary windings and is configured to be made by a multifilar winding wire such that electrical properties of each of the at least one secondary winding is identical.

In some examples, the at least one configurable transformer corresponds at least two transformers connected in series or parallel, the at least one secondary winding comprise a single secondary winding, and the at least one primary winding comprises a single primary winding, wherein each configurable transformer has a same turn ratio.

As another example, referring back to FIGS. 8A-B, the configurable transformer can have three primary windings connected in parallel and at least two secondary windings 801 connected in parallel to obtain a first required output NAC voltage and each configurable transformer has a same turn ratio, as shown in example 800a, and the configurable transformer can have three primary windings connected in parallel and at least two secondary windings 807a, 807b, 807c connected in parallel to obtain a second required output NAC voltage and each configurable transformer has a same turn ratio, as shown in example 800b. In some examples, the at least one toggle comprises at least one manual mechanical switch or jumpers to manually select the first voltage or the second voltage. In some examples, the at least one toggle comprises mechanical or solid-state relays to select the first voltage or the second voltage by an electric circuit, a microcontroller, or a processor coupled to the at least one configurable transformer in response to a command from a user or user interface (e.g., user interface component 1410 from FIG. 14).

As yet another example, referring back to FIGS. 9A-B, multiple transformers with a single primary winding and a single secondary winding may have the primary windings of the transformers 901a, 901b, 901c connected in series and the secondary windings 903a, 903b, 903c in parallel to obtain a first required output NAC voltage, as shown in example 900a, and multiple transformers with a single primary winding and a single secondary winding may have the primary windings of the transformers 901a, 901b, 901c connected in series and the secondary windings 907a, 907b, 907c in series to obtain a second required output NAC voltage, as shown in example 900b.

In addition, the method 1500 may also include: providing, at block 1503b, at least one toggle configured to switch a connection of the at least one secondary winding in parallel connection or series connection, a connection of the at least one primary winding in parallel connection or series connection, or a connection of the at least one configurable transformer in parallel connection or series connection. In some examples, the at least one toggle comprises at least one manual mechanical switch or jumpers to manually select the first voltage or the second voltage. In some examples, the at least one toggle comprises mechanical relays or solid-state relays to select the first voltage or the second voltage by an electric circuit, a microcontroller, or a processor coupled to the at least one configurable transformer. In some examples, the first voltage is 25 Vrms and the second voltage is 70 Vrms.

As an example, referring back to FIG. 3, the configurable transformer may have secondary windings with four switches 303a, 303b, 303c, 303d such that the output voltage levels can be selected manually or in response to a command from a user or user interface.

As another example, referring back to FIG. 6, the configurable transformer 600 may have primary windings with four switches 603a, 603b, 603c, 603d such that the output voltage levels can be selected manually or in response to a command from a user or user interface.

As another example, referring back to FIG. 10A, multiple transformers may have configurable secondary windings 1003a, 1003b, 1003c connections using four switches 1005a, 1005b, 1005c, 1005d when the primary windings are connected in parallel.

As another example, referring back to FIG. 10B, multiple transformers 1007a, 1007b, 1007c may have configurable secondary windings 1009a, 1009b, 1009c connections using four switches 1011a, 1011b, 1011c, 1011d when the primary windings are connected in series.

As yet another example, referring back to FIG. 13, four transformers 1301a, 1301b, 1301c, 1301d with configurable secondary connections using six switches 1303a, 1303b, 1303c, 1303d, 1303e, 1303f when the primary windings are connected in parallel.

In addition, the method 1500 may further include: providing, at block 1503c, an amplifier configured to adjust the output NAC voltage level.

At block 1505, the method 1500 may include: outputting the first voltage or the second voltage in response the combination of connecting the at least one secondary winding, the at least one primary winding, or the at least one configurable transformer in parallel connection or series connection and the number of the at least one configurable transformer, a number of the at least one secondary winding, or a number of the at least one primary winding and a selection of the at least one toggle.

In some examples, the method 1500 may further include providing: a single driver, wherein the at least one toggle comprises: (a) at least one double-pole-double-throw (DPDT) switch or relay or (b) a single 4-pole-double throw switch or relay.

As an example, referring back to FIG. 4, the transformer 400 may include configurable transformer with two DPDT relays 403, 405 which only require a single driver.

As another example, referring back to FIG. 7, the transformer 700 may include a configurable transformer with two DPDT relays 703, 705 which only requires a single driver.

As another example, referring back to FIG. 11A, the example 1100a may include a configurable secondary windings using two DPDT relays 1103a, 1103b which only requires a single driver when the primary windings are connected in parallel.

As another example, referring back to FIG. 11B, the example 1100b may include a configurable secondary windings using two DPDT relays 1109a, 1109b which only requires a single driver when the primary windings are connected in series.

As another example, referring back to FIG. 12A, the example 1200a may include an implementation of two paralleled transformers 1201a, 1201b with a configurable secondary winding 1209 using two DPDT relays 1203, 1205, a relay circuit, and a single driver.

As another example, referring back to FIG. 12B, the example 1200b may include an implementation of two paralleled transformers 1211a, 1211b with a configurable primary windings 1209 using two DPDT relays 1213, 1215, relay circuit, and a single driver.

In some examples, the method 1500 may include a relay circuit. The at least one configurable transformer comprises at least two at least one configurable transformers connected in parallel using the relay circuit. The at least one secondary winding comprises a single secondary winding. The at least one primary winding comprises at least three primary windings.

As an example, referring back to example 1200a of FIG. 12A, two paralleled transformers 1201a, 1201b have configurable secondary windings 1209 using two DPDT relays 1203, 1205, and a relay circuit. Specifically, example 1200a of FIG. 12A shows an example of connecting two paralleled transformers 1201a, 1201b with a single primary winding 1211 and three secondary windings 1209 in parallel. Although two transformers 1201a, 1201b are used, the same relay circuit can be used and it is not necessary to increase the number of relays 1203, 1205 as long as the power ratings of the relays 1203, 1205 are high enough to handle the combined output power of the two transformers 1201a, 1201b.

As an example, referring back to example 1200b of FIG. 12B, two paralleled transformers 1211a, 1211b have configurable primary windings 1209 using two DPDT relays 1213, 1215 and a single relay circuit. Specifically, example 1200b of FIG. 12B shows an example of connecting two identical transformers 1211a, 1211b with three primary windings 1209 and a single secondary windings 1219 in parallel to double the power capability.

Aspects of the present disclosure may be implemented as a system, a method, and/or a computer program product at any possible technical detail level of integration. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire. Non-transitory computer-readable media explicitly exclude transitory signals.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language, and conventional procedural programming languages.

Aspects of the present disclosure are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via

the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference in the specification to “one aspect” or “an aspect” of the present disclosure, as well as other variations thereof, means that a particular feature, structure, characteristic, and so forth described in connection with the aspect is included in at least one aspect of the present disclosure. Thus, the appearances of the phrase “in one aspect” or “in an aspect,” as well any other variations, appearing in various places throughout the specification are not necessarily all referring to the same aspect.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

It will be appreciated that various implementations of the above-disclosed and other features and functions, or alternatives or varieties thereof, may be desirably combined into many other different systems or applications. Also that various presently unforeseen or unanticipated alternatives, modifications, variations, or improvements therein may be subsequently made by those skilled in the art which are also intended to be encompassed by the following claims.

It should be understood that the application is not limited to the details or methodology set forth in the following description or illustrated in the figures. It should also be understood that the phraseology and terminology employed herein is for the purpose of description only and should not be regarded as limiting.

While the foregoing disclosure discusses illustrative aspects and/or embodiments, it should be noted that various changes and modifications could be made herein without departing from the scope of the described aspects and/or embodiments as defined by the appended claims. Furthermore, although elements of the described aspects and/or embodiments may be described or claimed in the singular, the plural is contemplated unless limitation to the singular is explicitly stated. Additionally, all or a portion of any aspect and/or embodiment may be utilized with all or a portion of any other aspect and/or embodiment, unless stated otherwise.

What is claimed is:

1. An audio notification appliance circuit (NAC) configured to manage an output voltage for an alarm system comprising:
at least one configurable transformer having at least one secondary winding and at least one primary winding, wherein the at least one configurable transformer is configured to set an output NAC voltage level to a first voltage or a second voltage based on connecting the at least one secondary winding, the at least one primary winding, or the at least one configurable transformer in parallel connection or series connection, and a number of the at least one configurable transformer, a number of the at least one secondary winding, or a number of the at least one primary winding;
at least one toggle is configured to, in response to receiving a command, switch a connection of the at least one secondary winding in parallel connection or series connection, a connection of the at least one primary winding in parallel connection or series connection, or a connection of the at least one configurable transformer in parallel connection or series connection; and
an amplifier configured to adjust the output NAC voltage level to either the first voltage or the second voltage.

2. The NAC of claim 1, wherein the at least one secondary winding comprises at least two secondary winding each having a same number of turns and is configured to be wounded individually around a core of the at least one configurable transformer.

3. The NAC of claim 1, wherein the at least one secondary winding comprises at least two secondary winding each having a same number of turns and is configured to be made by a trifilar winding wire such that electrical properties of each of the at least one secondary winding is identical.

4. The NAC of claim 1, wherein the at least one toggle comprises at least one mechanical switch or jumpers to select the first voltage or the second voltage.

5. The NAC of claim 1, wherein the at least one toggle comprises mechanical relays or solid-state relays to select the first voltage or the second voltage by an electric circuit, a microcontroller, or a processor coupled to the at least one configurable transformer.

6. The NAC of claim 1, further comprising:
a single driver, wherein the at least one toggle comprises: (a) at least one double-pole-double-throw (DPDT) switch or relay or (b) a single 4-pole-double-throw switch or relay.

7. The NAC of claim 1, wherein the at least one primary winding comprises at least two primary windings and is configured to be wounded individually around a core of the at least one configurable transformer.

8. The NAC of claim 1, wherein the at least one primary winding comprises at least two primary windings and is configured to be made by a multi-filar winding wire such that electrical properties of each of the at least one secondary winding is identical.

9. The NAC of claim 1, wherein the at least one configurable transformer corresponds at least two transformers connected in series or parallel, the at least one secondary winding comprise a single secondary winding, and the at least one primary winding comprises a single primary winding, wherein each configurable transformer has a same turn ratio.

10. The NAC of claim 9, wherein the at least one toggle comprises at least one mechanical switch or jumpers to select the first voltage or the second voltage.

11. The NAC of claim 9, wherein the at least one toggle comprises mechanical or solid-state relays to select the first voltage or the second voltage by an electric circuit, a microcontroller, or a processor coupled to the at least one configurable transformer.

12. The NAC of claim 9, further comprising:
a single driver, wherein the at least one toggle comprises: at least (a) two double-pole-double-throw (DPDT) switches or relays or (b) a single 4-pole-double-throw switch or relay.

13. The NAC of claim 1, further comprising:
a relay circuit,
wherein the at least one configurable transformer comprises at least two at least one configurable transformers with a single primary winding and at least two secondary windings connected in parallel using the relay circuit.

14. The NAC of claim 1, further comprising:
a relay circuit,
wherein the at least one configurable transformer comprises at least two configurable transformers connected in parallel using the relay circuit,
wherein the at least one secondary winding comprises a single secondary winding,
wherein the at least one primary winding comprises at least two primary windings.

15. The NAC of claim 1, wherein the first voltage is 25 Vᵣₘₛ and the second voltage is 70 Vᵣₘₛ.

16. A method of controlling an alarm system, comprising:
providing an audio notification appliance circuit (NAC) for managing an output voltage of the alarm system, comprising:
at least one configurable transformer having at least one secondary winding and at least one primary winding, wherein the at least one configurable transformer is configured to set an output NAC voltage level to a first voltage or a second voltage based on a combination of connecting the at least one secondary winding, the at least one primary winding, or the at least one configurable transformer in parallel connection or series connection, and a number of the at least one configurable transformer, a number of the at least one secondary winding, or a number of the at least one primary winding,
at least one toggle configured to, in response to receiving a command, switch a connection of the at least one secondary winding in parallel connection or series connection, a connection of the at least one primary winding in parallel connection or series connection, or a connection of the at least one configurable transformer in parallel connection or series connection, and
an amplifier configured to adjust the output NAC voltage level; and
outputting the first voltage or the second voltage in response the combination of connecting the at least one secondary winding, the at least one primary winding, or the at least one configurable transformer in parallel connection or series connection and the number of the at least one configurable transformer, a number of the at least one secondary winding, or a number of the at least one primary winding and a selection of the at least one toggle.

17. The method of claim 16, wherein the at least one secondary winding comprises at least two secondary winding each having a same number of turns and is configured to be wounded individually around a core of the at least one configurable transformer.

18. The method of claim 16, wherein the at least one secondary winding comprises at least two secondary winding each having a same number of turns and is configured to be made by a multi-filar winding wire such that electrical properties of each of the at least one secondary winding is identical.

19. The method of claim 16, wherein the at least one primary winding comprises at least two primary windings and is configured to be wounded individually around a core of the at least one configurable transformer.

20. An alarm system, comprising:
at least one audible alarm to generate an audible signal, and
an audio notification appliance circuit (NAC) for managing an output voltage of the at least one audible alarm, comprising:
at least one configurable transformer having at least one secondary winding and at least one primary winding, wherein the at least one configurable transformer is configured to set an output NAC voltage level to a first voltage or a second voltage based on connecting the at least one secondary winding, the at least one primary winding, or the at least one configurable transformer in parallel connection or series connection, and a number of the at least one configurable transformer, a number of the at least one secondary winding, or a number of the at least one primary winding;
at least one toggle configured to, in response to receiving a command, switch a connection of the at least one secondary winding in parallel connection or series connection, a connection of the at least one primary winding in parallel connection or series connection, or a connection of the at least one configurable transformer in parallel connection or series connection; and
an amplifier configured to adjust the output NAC voltage level to either the first voltage or the second voltage.
